(19) United States
(12) Patent Application Publication
(10) Pub. No.: US 2013/0241351 A1
(43) Pub. Date: Sep. 19, 2013

(54) Thin Plate Vibration Device and a Method of Producing the Same

(71) Applicant: NGK INSULATORS, LTD., Aichi-prefecture (JP)

(72) Inventors: Jungo Kondo, Miyoshi-city (JP); Yuichi Iwata, Nagoya-city (JP); Tetsuya Ejiri, Kasugai-city (JP)

(73) Assignee: NGK INSULATORS, LTD., Aichi-prefecture (JP)

(21) Appl. No.: 13/789,837

(22) Filed: Mar. 8, 2013

(30) Foreign Application Priority Data
Mar. 19, 2012 (JP) 2012-062276

(51) Int. Cl. H01L 41/09; H01L 41/332

(52) U.S. Cl. CPC H01L 41/09; H01L 41/332
USPC 310/323.01; 216/20

(57) ABSTRACT

A thin plate type vibration device 10 includes a vibration layer 2 composed of an oxide single crystal. The vibration layer 2 includes a first main face 2a and a second main face 2b, and further includes a fixed end part 2e, a free end part 2c and a central vibration part 2d provided between the fixed end part and free end part. The device 10 further includes an anchor part 7 composed of an oxide single crystal or a silicon single crystal and bonded to the fixed end part 2e of the vibration layer 2 at the first main face 2a. The device further includes a weight part 6 composed of an oxide single crystal or a silicon single crystal and bonded to the free end part 2c at the first main face 2a.

This application claims the benefit of Japanese Patent Application No. P2012-062276 filed on Mar. 19, 2012, the entirety of which is incorporated by reference.

### TECHNICAL FIELD

The present invention relates to a vibration electricity generation device for obtaining electricity from vibration energy at a high conversion rate, pressure sensor and acceleration sensor. Specifically, the present invention relates to improvement in precision of thickness and vibration stability of a thin part such as a diaphragm or cantilever.

### BACKGROUND ARTS

Until now, it has been applied micro machining technique of silicon to pressure and acceleration sensors etc.

According to Japanese Patent Publication No. H05-142247A, a groove is formed on a silicon substrate so as to define a supporting part, a weight part capable of vibration and a cantilever connecting the supporting and weight part by providing the groove to provide a semiconductor sensor. As an acceleration is applied on the sensor, the weight parts is vibrated to apply distortion and stress on the cantilever. The stress is subjected to piezoelectric conversion to provide an electricity generation device, or the stress is used to measure a change of a resistance to detect the acceleration or the like. Further, an electrode is formed on a first main face of the weight part and another fixed electrode is formed on an opposing second main face so that a change of the electrostatic capacitance is measured to detect the acceleration or the like. According to the structure, the weight part, cantilever and supporting part are formed by etching the silicon substrate to provide an integrated structure.

According to the sensor described in Japanese Patent Publication No. H05-142247A, it is necessary to make the thickness of the cantilever part very small so that the weight part can be readily vibrated. The cantilever part may be readily fractured and problematic. Further, the thin part of the cantilever is formed by the etching, so that it is difficult to adjust the thickness at a predetermined value at a high precision.

This is due to the deviations of thickness of the silicon substrate before the etching and etching conditions.

Further, it is disclosed a vibration electricity generating device in an article “IMEC Realized Vibration Electricity Generation Device of 50-fold Output by MEMS Technique” in “Nikkei Electronics” January, 2012, page 13.

According to the structure, similar to the cantilever described above, it is provided a weight part for generating vibration, an anchor part (supporting part) functioning as the fulcrum of the vibration and a beam part (cantilever). An piezoelectric device provided in the beam part functions to convert the distortion stress generated in the beam part to a voltage based on its piezoelectric effect to realize electricity generation. According to the structure, it is used a wafer type substrate utilizing silicon wafer having SOI (Si On Insulator) structure.

As a method of producing the SOI wafer, it is known two kinds of methods; SIMOX (Separation By IMplantation of OXygen) method and Adhesion method. SIMOX method was mainly developed by IBM Corporation. According to SIMOX, oxygen molecules are implanted into the wafer from a surface of silicon crystal by ion implantation and the wafer is oxidized at a high temperature to form an insulting film of silicon oxide inside of the silicon crystal. At present, so-called Smart-Cut method is popular because the obtained surface properties are superior than those obtained by SIMOX method. According to Smart-Cut method, an oxide film is formed on a surface of a bulk wafer, which is then adhered onto a surface of another unprocessed bulk wafer, and the processed wafer with the oxide film is then peeled off. The thickness after the peeling is controlled by a distance between the surface of the wafer and hydrogen ions implanted in advance deeper than the oxide film. The wafer after the peeling is then subjected to surface polishing by means of chemical mechanical polishing (CMP). Smart-Cut method requires additional steps for producing the SOI wafer compared with the SOI wafer of bulk silicon, so that the production cost of the SOI wafer is higher.

In the case that, however, the cantilever part of silicon single crystal is formed by etching, the fracture of the cantilever part tends to occur and its thickness is difficult to control, as described above.

For solving this problem, it is disclosed in Japanese Patent Publication No. H07-221323A a three-layer structure of silicon/Au/silicon. According to the descriptions of the publication, the Au layer functions as a stopping layer of the etching, so that the precision of the thickness of the cantilever can be improved. This structure is, however complex and therefore its production cost is considered to be high.

Further, according to Japanese Patent Publication No. H06-216396A, a glass substrate is bonded to a silicon substrate by anodic bonding so that the glass substrate functions as a cantilever for detecting an acceleration. The glass substrate is flat without any weight part.

In the case that the cantilever parts are formed from silicon single crystal, the above problems are caused as described above. It is thus disclosed, in Japanese Patent Publication No. H05-325274A, that a cantilever part is made of a film of a piezoelectric polycrystalline such as AlN, ZnO, Ta₂O₃, PbTiO₃, Bi₄Ti₃O₁₂, BaTiO₃ and LiNbO₃. The piezoelectric polycrystalline film may be formed by vapor deposition, sputtering, CVD or sol-gel methods. It is further disclosed that a plurality of electrodes and piezoelectric polycrystalline films are provided and they are bonded with each other by soldering, an adhesive or the like.

### SUMMARY OF THE INVENTION

According to Japanese Patent Publication No. H05-325274A, the cantilever part is made of a piezoelectric poly-crystal such as AlN, ZnO, Ta₂O₃, PbTiO₃, Bi₄Ti₃O₁₂, BaTiO₃ and LiNbO₃ (LN) and not of silicon single crystal. In these applications, for causing vibration efficiently, it is necessary to provide a weight part and to make the cantilever part as thin as possible. As the cantilever part is made thinner, however, the amplitude of the vibration tends to be large even at a low stress. In the case that the weight part is provided on a free vibration end of the cantilever part at the same time, the amplitude of the vibration becomes larger, resulting in a large deformation at a high speed, in combination with the thin cantilever part.

According to the cantilever structure as described in Japanese Patent Publication No. H05-325274A, however, in the case that the cantilever film is produced by the methods as described above, inner stress is induced because of the polycrystalline or amorphous microstructure of the film. Warping of the device may be thereby caused due to the influence of the inner stress, resulting in deviation of initial positions of the cantilevers in products. In the case that the cantilever is used as an acceleration sensor, it is required a complex compensation circuit for compensating the deviation of the initial positions.

Further, in the case that the inner stress is present, observed dislocation value may be changed in the cases that the acceleration is changed positively and negatively. In the case that the acceleration is obtained from the dislocation value, it is proved be impossible to measure the acceleration accurately without a compensation circuit of compensating the change of the dislocation value. Further, this phenomenon becomes more considerable as the initial warping is larger. Thus, in the case that the warping is deviated in products, the compensation factors required for the compensation circuit are also changed for the individual products. The actual application has been thereby difficult.

A method of measuring an acceleration will be described below. Generally, as an acceleration “G” is applied on an object having a mass “M”, a force “F” (=MG) is generated. Further, in the case that the force “F” is applied on the cantilever structure as shown in FIG. 5, the relationship of “F=k×” is satisfied, provided that “k” represents a spring constant of the cantilever and “x” represents a dislocation. Therefore, the dislocation “x” and spring constant “k” are correlated with each other according to a linear function. The acceleration can thereby be calculated based on the detected dislocation “x”, which provides the principle of measurement of acceleration.

However, in the cantilever of the thin plate structure by producing the film as described above, a residual stress is caused. The dislocations are different in the cases that the acceleration is changed positively or negatively, so that it is difficult to measure the acceleration accurately. As to the other kinds of applications, the dislocations are different with each other in the positive and negative directions. This phenomenon causes deviation in absolute values in various kinds of sensors and in generation powers.

The cause of the deviation of the dislocations corresponding to the positive and negative accelerations described above has not been clearly understood. It is, however, speculated that inner stress in the vibration layer constituting the cantilever would induce the warping of the cantilever to result in the deviation. That is, in the case that the directions of the warping and acceleration are opposite with each other, the dislocation is proved to become smaller. It is speculated that the force “F” due to the acceleration “G” is cancelled by the force induced by the warping in the opposite direction.

An object of the present invention is, in a structure of thinning a cantilever part and of providing a weight part at a free vibration end of the cantilever part, to enable accurate control of a thickness of the cantilever part and to reduce the deviation of dislocations corresponding to positive and negative accelerations.

The present invention provides a thin plate type vibration device. The vibration device includes a vibration layer, an anchor part and a weight part.

The vibration layer comprises an oxide single crystal and first and second main faces. The vibration layer further includes a fixed end part, a free end part and a central vibration part provided between the fixed and free end parts. The anchor part comprises an oxide single crystal or silicon single crystal, and bonded to the fixed end part of the vibration layer at the first main face. The weight part comprises an oxide single crystal or silicon single crystal and is bonded to the free end part at the first main face.

The present invention further provides a method of producing the thin plate-type vibration device. The method includes the steps of bonding the first main face of the vibration layer to an integrated flat plate comprising the oxide single crystal or silicon single crystal, and of subjecting the flat plate to wet etching to form the anchor and weight parts.

According to the structure of the present invention, the anchor part made of the oxide or silicon single crystal and the weight part made of the oxide or silicon single crystal are bonded to the fixed and free end parts, respectively of the vibration layer made of the oxide single crystal, so that the central end part faces a space between the anchor and weight parts.

As the vibration layer can be produced by subjecting a bulk of an oxide single crystal plate without internal stress to thinning, its thickness after the thinning can be made precisely controlled and warping can be prevented. The deviation of the initial position of the cantilever can be thereby prevented. In addition to this, the vibration dislocation of the vibration layer can be made large according to the inventive structure. Further, according to the structure, the difference of the dislocations corresponding to the positive and negative accelerations can be reduced, so that the structure can be operated stably for a long time. The industrial applicability of the present invention is thus considerable.

### BRIEF DESCRIPTION OF THE DRAWINGS

FIG. 1(a) is a view schematically showing a vibration layer 2 bonded with a flat plate 1, and FIG. 1(b) is a view schematically showing a device 10 according to an embodiment of the present invention.

FIG. 2(a) is a view schematically showing a vibration layer 2 bonded with flat plates 1A and 1B, and FIG. 2(b) is a view schematically showing a device 10A according to an embodiment of the present invention.

FIG. 3 is a view schematically showing a device 10B according to an embodiment of the present invention.

FIG. 4 is a view schematically showing a device 10C according to an embodiment of the present invention.

FIG. 5 is a view schematically showing a device provided in a system 21 of measuring a capacitance.

### EMBODIMENTS OF THE INVENTION

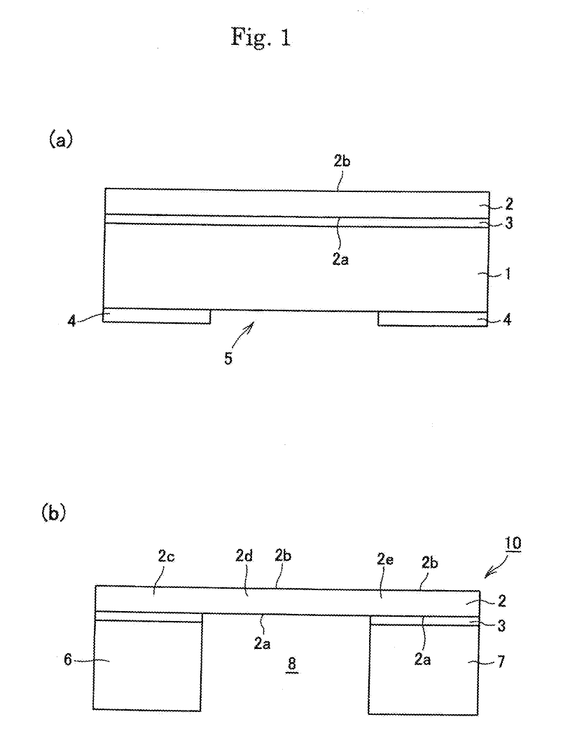

Embodiments of the present invention will be described first referring to attached drawings. First, a flat plate 1 is bonded to an oxide single crystal substrate for forming a vibration layer. According to the present embodiment, both of them are bonded through an adhesive layer 3. Then, the oxide single crystal substrate is polished to a predetermined thickness to form a vibration layer 2 to obtain a structure shown in FIG. 1(a).

According to the present embodiment, a second main face 2b faces a space. Masks 4 are provided on a predetermined positions of the flat plate 1 to form an opening 5 uncovered by the masks.

Then, the flat plate is etched from the opening 4 to form a space 8 so that a main face 2a of the vibration layer 2 faces to the space. The flat plate 1 is thereby separated to an anchor part 7 and a weight pat 6. According to the thus obtained device 10, a fixed end part 2e of the vibration layer 2 is fixed to the anchor part 7 so that a free end part 2c with the weight part 6 and the central vibration part 2d vibrates.

Besides, according to the present embodiment, it is shown a method of forming the space 8 by etching. The space 8 may be formed by forming a groove using an outer peripheral edge alone or by sandblasting alone or in combination.

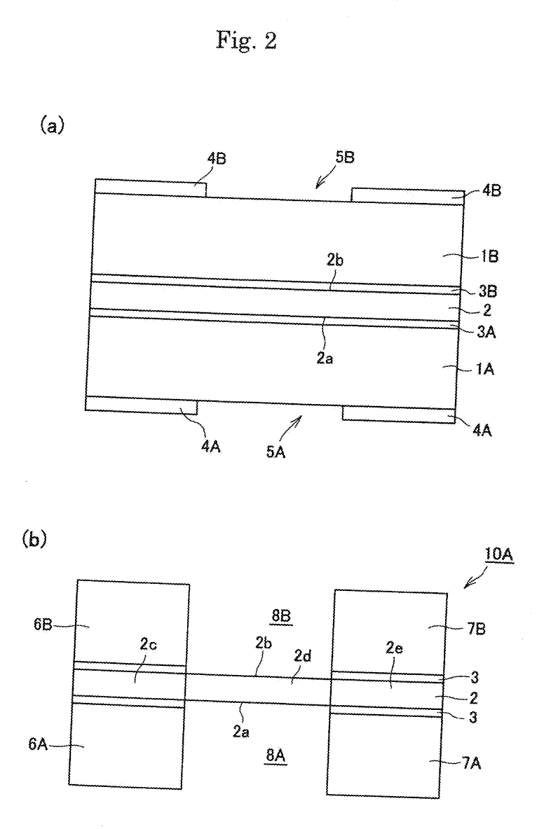

According to an embodiment of FIG. 2, a first flat plate 1A is bonded to the first main face 2a and a second flat plate 1B is bonded to the second main face 2b of the vibration layer 2 having a predetermined thickness, respectively. According to the present embodiment, the vibration layer 2 and flat plates 1A and 1B are bonded through adhesive layers 3A and 3B, respectively. Masks 4A and 4b are provided on predetermined positions of the flat plates 1A and 1B, respectively, to form openings 5A and 5B for etching by the masks 4A and 4B.

Then, the vibration layer 2 is etched from the openings 5A and 5B, respectively, to form spaces 8A and 8B so that the main faces 2a and 2b of the vibration layer 2 is exposed to the spaces. The flat plates 1A and 1B are separated to anchor parts 7A and 7B and weight parts 6A and 6B, respectively. In the thus obtained device 10A, the fixed end part 2e of the vibration layer 2 is fixed to the anchor parts 7A and 7B so that the free end part 2c with weight parts 6A and 6B and central vibration part 2d vibrate. By further providing the second anchor part and second weigh part as described above, the symmetry of the whole vibration structure is improved and its vibration state can be further stabilized.

Besides, according to the present embodiment, it is shown a method of forming the spaces 8A and 8B by etching. The spaces 8A and 8B may be formed by forming a groove using an outer peripheral edge alone or by sandblasting alone or in combination.

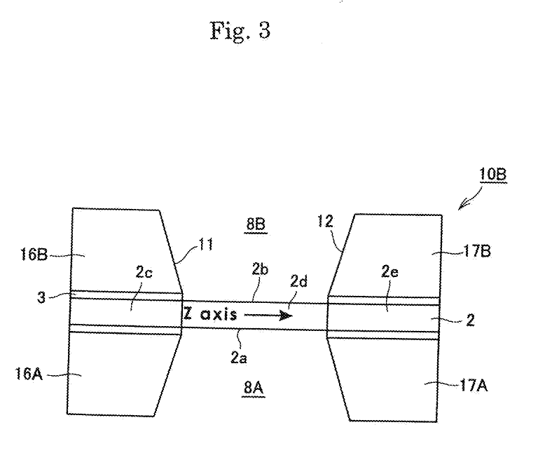

According to a device 10B shown in FIG. 3, a fixed end part 2e of the vibration layer 2 is fixed to anchor parts 17A and 17B and the free end part 2c with the weight parts 16a and 16B vibrates together with the central vibration part 2d. Further, according to the present embodiment, the vibration layer 2 is composed of an X plate or Y plate of an oxide single crystal. Further, wall faces of the fixed end parts 17A and 17B facing the spaces 8A and 8B form inclined faces 12, and wall faces of the weight parts 16A and 16B facing the spaces 8A and 8B form inclined faces 11.

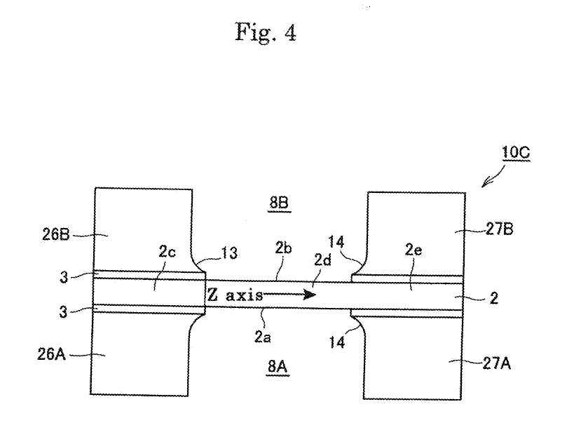

According to a device 10C of FIG. 4, a fixed end part 2e of the vibration layer 2 is fixed to anchor parts 27A and 27B and the free end part 2c with weight parts 26A and 26B vibrates together with the central vibration part 2d. Further, according to the present embodiment, the vibration layer 2 is made of a X plate or Y plate of an oxide single crystal. Further, wall faces of the fixed end parts 27A and 27B facing the spaces 8A and 8B form curved faces 14 near the vibration layer 2. Wall faces of the weight parts 16A and 16B facing the spaces 8A and 8B form curved faces 13 near the vibration layer 2.

The vibration layer is made of an oxide single crystal and includes first and second main faces. For improving the amplitude of the vibration, the thickness of the vibration layer may preferably be 50 μm or smaller and more preferably 15 μm or smaller. Further, on the viewpoint of stability of the structure, the thickness of the vibration layer may preferably be 1 μm or larger and more preferably be 3 μm or larger.

The oxide single crystal forming the vibration layer may preferably have a large elastic modulus and be resistive against etching. The oxide single crystal may more preferably be lithium niobate, lithium tantalate, lithium niobate-lithium tantalate solid solution or quartz.

The vibration layer may be composed of an X plate, Y plate or Z plate of an oxide single crystal, and further may be an off-cut X plate or off-cut Y plate. Particularly in an embodiment of forming the space by etching a flat plate, the oxide single crystal forming the vibration layer may preferably be composed of an X plate or Y plate because the etching rates of them are particularly small and preferable.

Although it is preferred that the thickness of the vibration layer is constant over the whole of the vibration layer, the central vibration part may be made thinner to some extent. Further, the thickness of the vibration layer can be made constant at a high precision by a known precise polishing process.

Further, the vibration layer, anchor part, second anchor part, weight part and second weight part may be adhered through an adhesive layer or directly bonded without such adhesive layer. The direct bonding method includes heat bonding, ambient temperature bonding, surface activation bonding, anodic bonding, ultrasonic bonding, plasma irradiation bonding and high temperature high pressure bonding. Further, the adhesive may preferably be a thermosetting resin such as epoxy, acrylic, urethane and polyimide resins and an UV curable resin.

The anchor part and second anchor part are made of an oxide single crystal or silicon single crystal. Such oxide single crystal includes those listed for the vibration layer as described above. However, the material of the anchor part or second anchor part is not necessarily same as that of the vibration layer.

Further, the weight part and second weight part is made of an oxide single crystal or silicon single crystal. Such oxide single crystal includes those listed for the vibration layer as described above. However, the material of the weight part or second weight part is not necessarily same as that of the vibration layer.

According to a preferred embodiment, as shown in the attached figures, the central vibration part 2d faces the space between the anchor and weight parts.

Further, according to a preferred embodiment, the anchor part, second anchor part, weight part and second weight part are composed of a same material. However, they may be made of different materials.

Further, according to a preferred embodiment, the vibration layer, anchor part, second anchor part, weight part and second weight part are made of a same material. In this case, it is preferred that the material has anisotropy so that it is easier to etch the material in one orientation and it is resistive against the etching of the material in another orientation. Actually, it is preferred that the bonding surface of the vibration layer bonded with the anchor, second anchor, weight or second weight part has a crystal axis resistive against etching. Further, it is preferred that the anchor, second anchor, weight or second weight part has a crystal axis susceptible to etching whose orientation is opposite to the bonding surface with the vibration layer.

According to a preferred embodiment, as illustrated in FIG. 1, the whole of another main face of the vibration layer faces a space. The space may be filled with atmosphere, or filled with air, or may be high vacuum or reduced pressure condition.

The etching may be dry etching or wet etching. However, wet etching is preferred, because the etching rate is higher and the thickness of the vibration layer and shapes of the anchor and fixed parts can be made uniform with stability.

Further, for reducing processing steps and tact, the processing of the groove may be carried out by combination of the grinding by an outer peripheral edge, excimer laser and/or blasting.

An etchant for the wet etching includes fluoric acid, fluoronitric acid and buffered fluoric acid (BHF) for oxide single crystals. Further, in the case of silicon, the etchant includes KOH and EDP in addition to the above listed etchants. Further, it is desired that it is used a mask resistant against the etchant and capable of functioning as an electrode. A material of the mask may thus preferably be a metal material having a high conductivity. Specifically, the mask material includes Au, Pt, Mo, Ti, Cr or the like for example.

The followings show the etching rates in the cases that the following materials are etched by a etchant (fluoric acid 50% water, at a temperature of 65° C.). The etching rate is shown on an unit of μm/hour.

LiNbO₃ (+X face): 0.25
LiNbO₃ (−X face): 0.25
LiNbO₃ (+Z face): 0.005
LiNbO₃ (−Z face): 30
LiTaO₃ (+X face): 1
LiTaO₃ (−X face): 1
LiTaO₃ (+Z face): 0.1
LiTaO₃ (−Z face): 2.4

### Quartz: 71

Further, the following is the etching rate in the case that silicon single crystal is etched by an etchant (KOH 25% water, at a temperature of 70° C.).

Silicon single crystal: 40

### EXAMPLES

### Inventive Example

A device 10B of FIG. 3 was produced according to the procedure described referring to FIG. 2.

It was used, as the vibration layer 2, an X plate or Y plate of lithium niobate single crystal, and the thickness of the vibration layer 2 was made 10 μm. It was used, as the flat plate 1, a Z plate of lithium niobate so that its +Z face was adhered to the vibration layer 2 and −Z face was exposed to the space. The thickness of the flat plate 1 was made 500 μm. The vibration layer 2 and flat plate 1 were adhered with a thermosetting resin. The mask 4 was made of Au and formed by photolithography.

Then, fluoric acid was used as an etchant for etching the flat plate 1 to form a space. The etching was carried out by immersing the flat plate in fluoric acid at an ambient temperature of 65° C. for 17 hours.

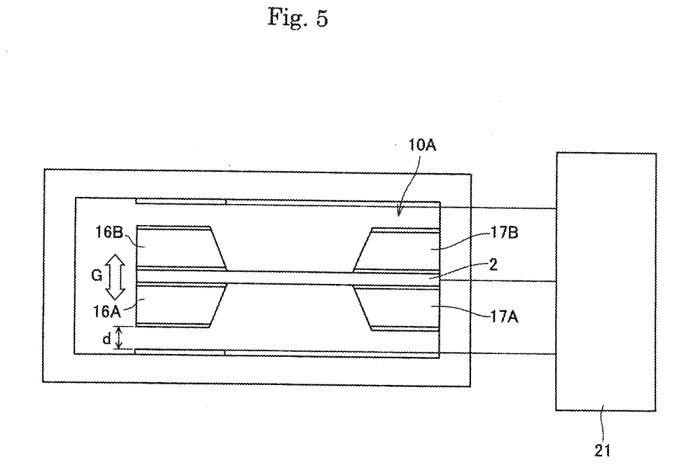

It was confirmed that the thus produced device was not warped. The characteristics as an acceleration sensor were then evaluated. As shown in FIG. 5, the device was set in a system 21 for measuring capacitance. An acceleration was applied in a range of +10G to −10G vertically on the cantilever by a vibration generator, so as to measure its dislocation. The capacitance between electrodes was measured to obtain an electrostatic capacitance, which was used to obtain a gap “d” between the electrodes. A shift of the gap “d” with respect to an initial position is defined as the dislocation. The thus obtained results were shown in FIG. 2. As a result, the acceleration and dislocation were proved to be changed linearly and the slope was proved to be constant with respect to each of the positive and negative accelerations.

TABLE 1

| Acceleration (G) | Dislocation (μm) |
|---|---|
| 10 | 5.00 |
| 8 | 4.00 |
| 6 | 3.00 |
| 4 | 2.00 |
| 2 | 1.00 |
| 0 | 0.00 |
| −2 | −1.00 |
| −4 | −2.00 |
| −6 | −3.00 |
| −8 | −4.00 |
| −10 | −5.00 |

### Comparative Example

A device was produced according to the same procedure as the Inventive Example, except that the vibration layer 2 was made of a polycrystalline ceramics (lithium niobate).

The cantilever of the thus produced device had a warping of about 5 μm as a whole. The characteristics as an acceleration sensor were evaluated according to the same procedure as the Inventive Example. The thus obtained results were shown in table 2. As a result, it was proved that, although the acceleration and dislocation were linearly changed, the slopes were different with each other with respect to the positive and negative accelerations. Further, the difference of the slopes was proved to be larger as the warping of the device was larger.

TABLE 2

| Acceleration (G) | Dislocation (μm) |
|---|---|
| 10 | 5.00 |
| 8 | 4.00 |
| 6 | 3.00 |
| 4 | 2.00 |
| 2 | 1.00 |
| 0 | 0.00 |
| −2 | −0.87 |
| −4 | −1.74 |
| −6 | −2.61 |
| −8 | −3.48 |
| −10 | −4.35 |

1. A thin plate type vibration device comprising:
a vibration layer comprising an oxide single crystal, a first main face and a second main face, said vibration layer further comprising a fixed end part, a free end part and a central vibration part provided between said fixed end part and said free end part;
an anchor part comprising an oxide single crystal or a silicon single crystal, said anchor part bonded to said fixed end part of said vibration layer at said first main face; and
a weight part comprising an oxide single crystal or a silicon single crystal, said weight part bonded to said free end part at said first main face.

2. The device of claim 1, wherein said oxide single crystal or silicon single crystal forming said anchor part is same as that forming said weight part.

3. The device of claim 1, wherein said second main face of said vibration layer faces a space over the whole of said second main face.

4. The device of claim 1, further comprising:
a second anchor part comprising an oxide single crystal or a silicon single crystal, said second anchor part bonded to said fixed end part of said vibration layer at said second main face; and
a second weight part comprising an oxide single crystal or a silicon single crystal, said second weight part bonded to said free end part at said second main face.

5. The device of claim 4, wherein said oxide single crystal or silicon single crystal forming said second anchor part is same as that forming said second weight part.

6. The device of claim 1, wherein said oxide single crystal forming said vibration layer is anisotropic, and wherein said vibration layer comprises an X plate or Y plate in a crystal axis at said main faces.

7. The device of claim 1, wherein said anchor part and said weight part are formed by wet etching of a flat plate comprising said oxide single crystal or said silicon single crystal.

8. The device of claim 4, wherein said second anchor part and said second weight part are formed by wet etching of a flat plate comprising said oxide single crystal or said silicon single crystal.

9. A method of producing the thin plate type vibration device of claim 1, the method comprising the steps of:
bonding said first main face of said vibration layer to a flat plate comprising said oxide single crystal or said silicon single crystal; and
subjecting said flat plate to wet etching to form said anchor part and said weight part.

10. A method of producing the thin plate-type vibration device of claim 4, the method comprising the steps of:
bonding said second main face of said vibration layer to a flat plate comprising said oxide single crystal or said silicon single crystal; and
subjecting said flat plate to wet etching to form said second anchor part and said second weight part.
